(19) United States
(12) Patent Application Publication
(10) Pub. No.: US 2024/0227391 A1
(43) Pub. Date: Jul. 11, 2024

(54) METHOD OF MANUFACTURING PATTERN-FORMED BOARD AND LIQUID JET APPARATUS

(71) Applicant: FUJIFILM Corporation, Tokyo (JP)

(72) Inventor: Tadashi KYOSO, Kanagawa (JP)

(73) Assignee: FUJIFILM Corporation, Tokyo (JP)

(21) Appl. No.: 18/611,677

(22) Filed: Mar. 20, 2024

Related U.S. Application Data
(63) Continuation of application No. PCT/JP2022/027492, filed on Jul. 13, 2022.

(30) Foreign Application Priority Data
Sep. 24, 2021 (JP) 2021-155806

(51) Int. Cl. B41J 2/045; B41J 25/304; B41M 3/00

(52) U.S. Cl. CPC B41J 2/04581; B41J 2/04503; B41J 2/04516; B41J 2/04526; B41J 2/04588; B41J 25/304; B41M 3/008

(57) ABSTRACT

In a case where a plurality of times of relative movement between a board and a liquid jet head are performed and liquid is jetted to the board from the liquid jet head during each relative movement to form a pattern on the board, a first relative movement is performed and the liquid is jetted from the liquid jet head to form a first pattern element on the board, a second relative movement is performed and the liquid is jetted from the liquid jet head to form a second pattern element at a position in contact with the first pattern element and to form the pattern including the first pattern element and the second pattern element, and a relative movement speed lower than a relative movement speed of the second relative movement is applied to the first relative movement.

### CROSS-REFERENCE TO RELATED APPLICATIONS

The present application is a Continuation of PCT International Application No. PCT/JP2022/027492 filed on Jul. 13, 2022 claiming priority under 35 U.S.C § 119(a) to Japanese Patent Application No. 2021-155806 filed on Sep. 24, 2021. Each of the above applications is hereby expressly incorporated by reference, in its entirety, into the present application.

### BACKGROUND OF THE INVENTION

### 1. Field of the Invention

The present invention relates to a method of manufacturing a pattern-formed board and a liquid jet apparatus.

### 2. Description of the Related Art

In ink jet printing, there is a case where it is desired to relatively improve drawing accuracy of a boundary position of a printing pattern. The drawing accuracy refers to position accuracy of dots, which are formed using ink, such as printing position accuracy.

JP2011-178100A discloses a fluid jet apparatus that superimposes second printing data formed using fluid jetted onto a recording medium on first printing data formed using the fluid jetted onto a recording medium.

The apparatus disclosed in JP2011-178100A obtains an elongation EY1 form a printing result of a first scanning operation, adjusts a relative speed between a workpiece W and a recording head in a second scanning operation to VxEY1, and superimposes the second printing data on the first printing data with high accuracy.

JP2015-229318A discloses an ink jet printer that uses a three-dimensional object as a medium of a printed matter. The device disclosed in JP2015-229318A changes a movement speed of an ink jet head according to a gap distance indicating a distance between a nozzle surface of the ink jet head and a medium to suppress the shift of a landing position and a variation in the landing position in a case where the gap distance is long.

### SUMMARY OF THE INVENTION

However, it may be desired to improve the position accuracy of a boundary position in a pattern that is formed using ink jet printing. That is, there may be a case where it is desired to improve the dimensional accuracy of a range to be printed.

The device disclosed in JP2011-178100A adjusts a jet timing in accordance with the expansion and contraction of a substrate in a case where a plurality of times of scanning operation are performed and printing is performed. However, since the device disclosed in JP2011-178100A is affected by a variation in the jetting characteristics of the ink jet head itself, the generation of satellites, and the like, it is difficult to avoid deterioration in print quality.

A distance between an ink jet head and a medium can be shortened in a device disclosed in JP2015-229318A, so that drawing accuracy can be improved. However, in a case where the distance between the ink jet head and the medium is excessively short, there is a concern that the ink jet head and the medium collide with each other. Since it is necessary to increase the distance between the ink jet head and the medium to avoid collision between the ink jet head and the medium, the improvement of drawing accuracy is limited.

The present invention has been made in consideration of such circumstances, and an object of the present invention is to provide a method of manufacturing a pattern-formed board and a liquid jet apparatus that can ensure constant position accuracy of a pattern.

A method of manufacturing a pattern-formed board according to an aspect of the present disclosure is a method of manufacturing a pattern-formed board by performing a plurality of times of relative movement between a board and a liquid jet head and jetting liquid to the board from the liquid jet head during each relative movement to form a pattern on the board. The method includes: performing a first relative movement and jetting the liquid from the liquid jet head to form a first pattern element on the board; performing a second relative movement and jetting the liquid from the liquid jet head to form a second pattern element at a position in contact with the first pattern element and to form the pattern including the first pattern element and the second pattern element; and applying a relative movement speed, which is lower than a relative movement speed of the second relative movement, to the first relative movement.

According to the method of manufacturing a pattern-formed board of the aspect of the present disclosure, a relative movement speed, which is lower than a relative movement speed applied to the second relative movement, is applied to the first relative movement. Accordingly, the first pattern element of which constant position accuracy is ensured is formed during the first relative movement, so that the constant position accuracy of the pattern can be ensured.

In case where three or more times of relative movement are performed, the second or subsequent relative movement can be included in the second relative movement. That is, a plurality of times of relative movement can be included in the second relative movement. Examples of the pattern include a functional pattern that is obtained in a case where liquid having functionality is dried and cured. Examples of the functional pattern include an electrical wiring pattern.

As the board, an electrical component mounting board on which electrical components are mounted may be applied or an electrical circuit board on which electrical components are not yet mounted may be applied.

In the relative movement, the liquid jet head may be fixed and the board may be moved in a board transport direction, or the board may be fixed and the liquid jet head may be moved in a head movement direction. In the relative movement, both the board and the liquid jet head may be moved.

In the relative movement, the liquid jet head may be moved in one direction of two directions orthogonal to each other and the board may be moved in the other direction thereof.

A liquid jet apparatus according to another aspect of the present disclosure is a liquid jet apparatus comprising a liquid jet head that jets liquid to a board, a moving device that moves the board and the liquid jet head relative to each other, at least one processor, and at least one memory that stores a command to be executed by the at least one processor. The at least one processor is configured to control the moving device to perform a first relative movement of a plurality of times of relative movement between the board and the liquid jet head, to jet the liquid to the board from the liquid jet head during the first relative movement to form a first pattern element on the board, to control the moving device to perform a second relative movement, to jet the liquid from the liquid jet head during the second relative movement to form a second pattern element at a position in contact with the first pattern element and to form a pattern including the first pattern element and the second pattern element, and to apply a relative movement speed, which is lower than a relative movement speed of the second relative movement, to the first relative movement.

According to the liquid jet apparatus of another aspect of the present disclosure, the same effects as the method of manufacturing a pattern-formed board according to the aspect of the present disclosure can be obtained.

An aspect in which an ink jet head is provided as the liquid jet head can be applied to the liquid jet apparatus.

In the liquid jet apparatus according to another aspect, the at least one processor may be configured to apply a driving frequency of the liquid jet head, which is applied to the jet of the liquid during the second relative movement, to the jet of the liquid during the first relative movement.

According to such an aspect, in a case where the same conditions as the jet of the liquid during the second relative movement are applied to the first relative movement, the volume of the liquid jetted per unit time during the second relative movement is not reduced. Accordingly, a reduction in the productivity of the pattern-formed board can be suppressed.

In the liquid jet apparatus according to another aspect, the at least one processor may be configured to control the moving device such that a relative movement speed lower than an average of a relative movement speed of the second or subsequent relative movement is applied to the first relative movement.

In such an aspect, the lowest relative movement speed among relative movement speeds applied to all the relative movements may be applied to the first relative movement.

In the liquid jet apparatus according to another aspect, the at least one processor may be configured to control the moving device such that a relative movement speed, which is ¾ times or less a relative movement speed set for the second relative movement, is applied to the first relative movement.

According to such an aspect, an influence of the variation of liquid droplets jetted from the liquid jet head are less likely to appear. Accordingly, constant landing accuracy can be ensured.

Examples of the variation of liquid droplets include a variation in jet direction, a variation in the volume of the jetted liquid droplet, and a variation in a jet position.

In the liquid jet apparatus according to another aspect, the at least one processor may be configured to select a liquid droplet size in which satellites are less likely to be generated in a case where a liquid droplet size to be applied the jet of the liquid during the first relative movement is to be selected from a plurality of types of liquid droplet sizes.

According to such an aspect, since a risk of the generation of satellites is suppressed, the formation of a pattern based on good jetting characteristics can be realized.

In the liquid jet apparatus according to another aspect, the at least one processor may be configured to select a smallest liquid droplet size in a case where a liquid droplet size to be applied the jet of the liquid during the first relative movement is to be selected from a plurality of types of liquid droplet sizes.

According to such an aspect, the formation of a pattern based on good jetting characteristics of the liquid jet head can be realized.

In the liquid jet apparatus according to another aspect, the liquid jet head may comprise a piezoelectric element that applies pressure to the liquid in a case where the liquid is jetted, and the at least one processor may be configured to supply a drive voltage, which includes one pulse-shaped voltage contributing to the jet, to the piezoelectric element in the jet of the liquid during the first relative movement.

According to such an aspect, since a risk of the generation of satellites during the jet of the liquid is suppressed, the formation of a pattern based on good jetting characteristics of the liquid jet head can be realized.

The liquid jet apparatus according to another aspect may further comprise a change device that changes a distance between the board and the liquid jet head, and the at least one processor may be configured to control the change device to apply a distance, which is shorter than a distance between the board and the liquid jet head applied to the second relative movement, as a distance between the board and the liquid jet head that is applied to the first relative movement.

According to such an aspect, the position accuracy of the pattern element can be improved in the formation of the pattern element during the first relative movement as a reference. Accordingly, position accuracy can be improved over the entire pattern to be formed on the board.

In the liquid jet apparatus according to another aspect, the at least one processor may be configured to jet the liquid to a boundary position of a pattern to be formed on the board during the first relative movement and to jet the liquid to a non-boundary position of a pattern to be formed on the board during the second relative movement.

According to such an aspect, the boundary position of the pattern that requires relatively high position accuracy is formed during the first relative movement in which relatively high position accuracy can be ensured. Accordingly, even though a variation occurs in the non-boundary position of the pattern to be formed during the second or subsequent relative movement, constant position accuracy can be ensured over the entire pattern.

A region having the area of one or more dots can be applied as the boundary position of the pattern.

In the liquid jet apparatus according to another aspect, the liquid jet head may jet conductive liquid having conductivity.

According to such an aspect, a conductive pattern having high position accuracy can be formed.

A conductive pattern formed on an electrical component can function as an electromagnetic wave shield for an electrical component. The conductive pattern can function as an electrical wiring pattern, an electrode, and the like that forms an electrical circuit.

In the liquid jet apparatus according to another aspect, an electrical component mounting board on which an electrical component is mounted may be applied as the board, and the at least one processor may be configured to jet the conductive liquid to an electrical component-disposition region, in which the electrical component is disposed, from the liquid jet head.

According to such an aspect, an electromagnetic wave shield having high position accuracy can be formed on the electrical circuit board on which the electrical component is disposed.

Configuration requirements of the liquid jet apparatus according to another aspect can be applied to configuration requirements of a method for manufacturing an electrical component mounting board according to another aspect.

According to the present invention, a relative movement speed, which is lower than a relative movement speed applied to the second relative movement, is applied to the first relative movement. Accordingly, the first pattern element of which constant position accuracy is ensured is formed during the first relative movement, so that the constant position accuracy of the pattern can be ensured.

### BRIEF DESCRIPTION OF THE DRAWINGS

FIG. 1 is a perspective view of an electrical component mounting board to which a method of manufacturing a pattern-formed board according to an embodiment is applied.

FIG. 2 is a schematic diagram of a pattern.

FIG. 3 is a schematic diagram of a pattern showing an example of a state of a target pattern.

FIG. 4 is a schematic diagram of a pattern showing an example of a state of a pattern that is actually generated.

FIG. 5 is a schematic diagram of a pattern in a case where satellites are generated.

FIG. 6 is a schematic diagram of a pattern that is formed using the method of manufacturing a pattern-formed board according to the embodiment.

FIG. 7 is a schematic diagram showing the formation of boundary dots.

FIG. 8 is a waveform diagram showing a first example of a drive voltage waveform.

FIG. 9 is a waveform diagram showing a second example of a drive voltage waveform.

FIG. 10 is a waveform diagram showing a third example of a drive voltage waveform.

FIG. 11 is a waveform diagram showing a fourth example of a drive voltage waveform.

FIG. 12 is a waveform diagram showing a fifth example of a drive voltage waveform.

FIG. 13 is a flowchart showing a procedure of the method of manufacturing a pattern-formed board according to the embodiment.

FIG. 14 is a diagram showing the overall configuration of a liquid jet apparatus according to an embodiment.

FIG. 15 is a schematic diagram of a lifting mechanism of the liquid jet apparatus shown in FIG. 14.

FIG. 16 is a functional block diagram showing an electrical configuration of the liquid jet apparatus shown in FIG. 14.

FIG. 17 is a block diagram showing a configuration example of the hardware of the liquid jet apparatus shown in FIG. 14.

### DESCRIPTION OF THE PREFERRED EMBODIMENTS

Preferred embodiments of the present invention will be described in detail below with reference to the accompanying drawings. In the present specification, the same components will be denoted by the same reference numerals and repeated description thereof will be omitted as appropriate.

### [Configuration of Electrical Component Mounting Board]

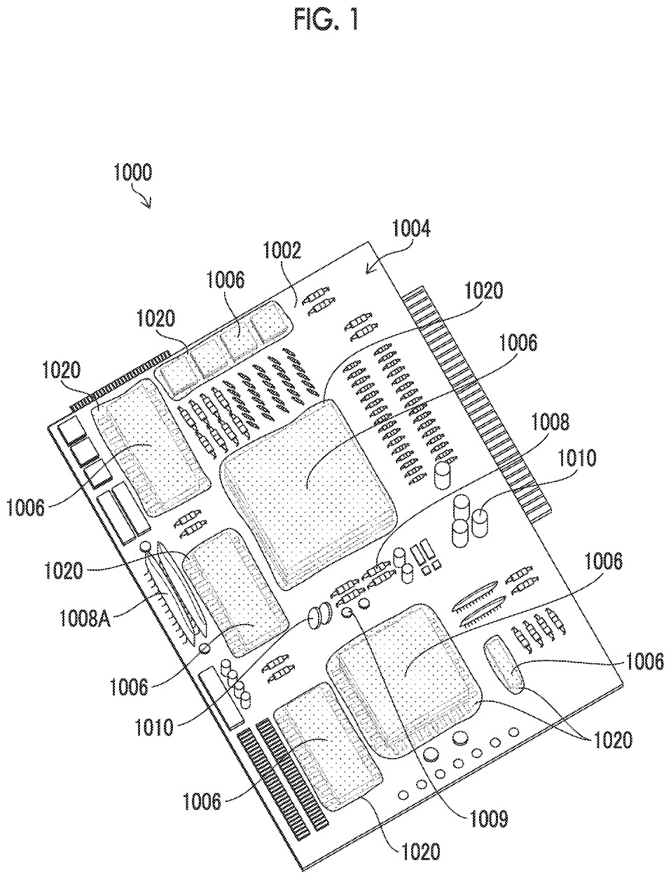

FIG. 1 is a perspective view of an electrical component mounting board to which a method of manufacturing a pattern-formed board according to an embodiment is applied. In the electrical component mounting board 1000 shown in FIG. 1, ICs 1006, resistors 1008, and capacitors 1010 are mounted on a component mounting surface 1004 of a printed wiring board 1002. Further, conductive patterns 1020 are formed on the ICs 1006 on the electrical component mounting board 1000. Insulating patterns are formed on lead wires of the ICs 1006 and electrodes electrically connected to the lead wires of the IC 1006. The insulating patterns are not shown.

Although FIG. 1 illustrates an aspect in which one surface of the printed wiring board 1002 is the component mounting surface 1004, the other surface of the printed wiring board 1002 may be a component mounting surface or both one surface and the other surface of the printed wiring board 1002 may be component mounting surfaces.

The IC 1006 is an electrical component of which an outer periphery is formed using a package, such as a resin and in which an integrated circuit is provided. Further, the IC 1006 has a structure in which electrodes are exposed to the outside of the package. The IC is an abbreviation for Integrated Circuit. Here, the electrical component may be referred to as an electronic component.

Further, the resistor 1008 may include a resistor array 1008A in which a plurality of electrical resistance elements are integrated using a package, such as a resin. The capacitor 1010 may include various capacitors, such as an electrolytic capacitor and a ceramic capacitor.

Liquid droplets of conductive ink are jetted from an ink jet head to a region where the conductive pattern 1020 is to be formed and a continuous body of the conductive ink is dried and cured, so that the conductive pattern 1020 is formed. The conductive ink disclosed in the embodiment is an example of conductive liquid having conductivity. The region where the conductive pattern 1020 is to be formed, which is disclosed in the embodiment, is an example of an electrical component-disposition region.

The conductive pattern 1020 functions as an electromagnetic wave shield for the purpose of suppressing electromagnetic waves received by the IC 1006 and suppressing electromagnetic waves emitted from the IC 1006. An insulating pattern functioning as an insulating member that ensures electrical insulation between the conductive pattern 1020 and the IC 1006, an adhesive member that ensures adhesiveness between the conductive pattern 1020 and the IC 1006, a member that ensures the flatness of a base of the conductive pattern 1020, and the like may be formed.

The resistors 1008, the capacitors 1010, and the like among the electrical components mounted on the printed wiring board 1002 are regions in which the conductive pattern 1020 is not formed, and at least a part of component regions in which electrical components not requiring an electromagnetic wave shield are disposed may be coated with an insulating coating. The electrical components not requiring an electromagnetic wave shield may include a diode, a coil, a transformer, a switch, and the like. Further, electrode regions in which electrical components are not mounted and exposed electrodes 1009 are disposed may be coated with an insulating pattern.

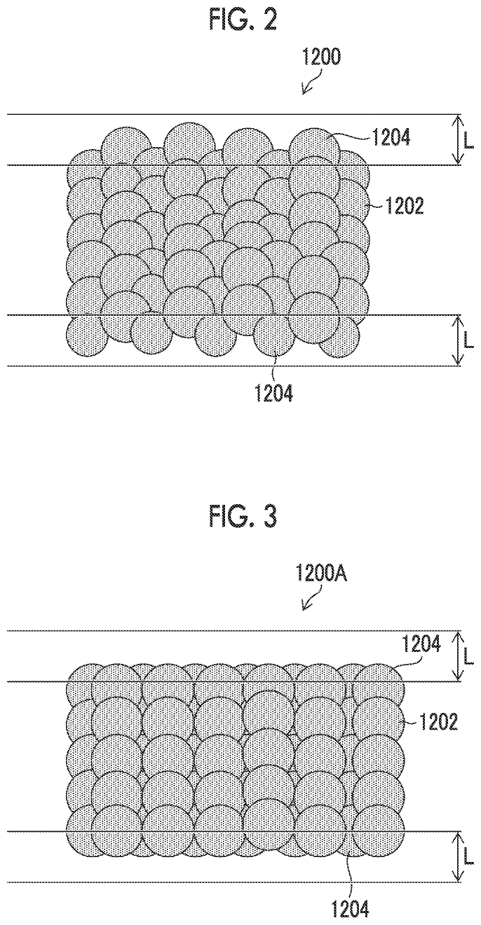

FIG. 2 is a schematic diagram of a pattern. An example in which printing is applied and conductive ink is used to form a conductive pattern 1200 will be described below. The conductive pattern 1200 includes a plurality of dots 1202. The plurality of dots 1202 include boundary dots 1204 that form boundary positions of the conductive pattern 1200.

### [Problem in Forming Conductive Pattern]

In recent years, as a result of miniaturization of electronic products, there is a tendency that electrical components are densely mounted on an electrical board, such as the electrical component mounting board 1000 shown in FIG. 1. In a case where the electrical component mounting board 1000 is coated with the conductive ink, the conductive pattern 1200 printed with the conductive ink has a problem in ensuring the accuracy of a size and the printing position accuracy of the boundary dots 1204 forming the boundary positions. Reference letter L shown in FIG. 2 denotes an allowable range of the printing position accuracy of the boundary dots 1204 of the conductive pattern 1200. The printing position accuracy indicates the position accuracy of the dots 1202 forming the conductive pattern and the position accuracy of the conductive pattern 1200.

In a case where the conductive pattern 1200 shown in FIG. 2 is printed on the electrical component mounting board 1000 shown in FIG. 1 and the width of the conductive pattern 1200 is larger than a target, the conductive ink adheres to an unnecessary position. For this reason, there is a concern that a short circuit of an electrical circuit formed on the electrical component mounting board 1000 occurs. For example, there may be a case where the printing position accuracy of the boundary positions of the conductive pattern 1200 is required to have an error of 100 μm or less.

In a case where an ink jet method is applied to print the conductive pattern 1200 in such a case, it is not easy to ensure a required printing position accuracy in the printing of the conductive pattern 1200 due to the influence of a variation in the characteristics of an ink jet head and an error in the adjustment of the printing position.

FIG. 3 is a schematic diagram of a pattern showing an example of a state of a target pattern. Since the positions of the boundary dots 1204 are aligned with each other in the conductive pattern 1200A shown in FIG. 3, the printing position accuracy of the boundary positions is ensured. Accordingly, the conductive pattern 1200A is a pattern appropriately printed.

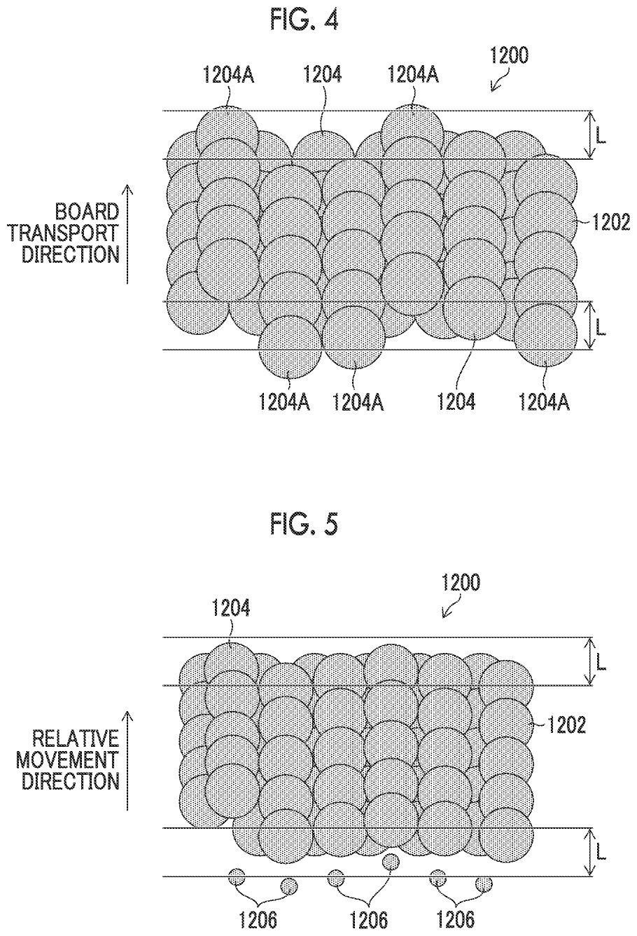

FIG. 4 is a schematic diagram of a pattern showing an example of a state of a pattern that is actually generated. FIG. 4 shows an example in which a board and an ink jet head are moved relative to each other in a relative movement direction to print the conductive pattern 1200.

With regard to the relative movement between the board and the ink jet head, the board may be moved relative to the ink jet head of which the position is fixed or the ink jet head be moved relative to the board of which the position is fixed. Of course, both the board and the ink jet head may be moved. An arrow shown in FIG. 4 indicates a board transport direction in which the board is transported relative to the fixed ink jet head.

In a case where a relative movement is described hereinafter, the relative movement means the relative movement between the board and the ink jet head unless otherwise specified. The same applies to terms including a relative movement, such as a relative movement direction and a relative movement speed. Further, the relative movement in the present embodiment is synonymous with scanning, and the like.

Landing positions of ink droplets may be shifted in the relative movement direction in the conductive pattern 1200 that is actually printed. The landing positions of ink droplets are synonymous with formation positions of the dots 1202. In the example shown in FIG. 4, boundary dots 1204A among the boundary dots 1204 are formed at positions beyond the allowable range L of the printing position accuracy.

The main reason why the boundary dots 1204A formed at the positions beyond the allowable range L of the printing position accuracy are generated is differences in individual jetting characteristics of a plurality of nozzles provided in the ink jet head. Examples of the jetting characteristics of each nozzle include the speed of a liquid droplet jetted from each nozzle, the volume of a liquid droplet, and the jet direction of a liquid droplet.

Since each nozzle has different jetting characteristics, a variation particularly occurs in the landing positions of each nozzle in the relative movement direction. For this reason, it is difficult to ensure the printing position accuracy of the conductive pattern 1200.

Further, if a sufficient distance is not ensured between the ink jet head and the electrical component mounting board 1000 in a case where the conductive pattern 1200 is to be printed on the electrical component mounting board 1000 shown in FIG. 1, collision between the ink jet head and an electrical component, such as the IC 1006, may occur.

Accordingly, it is necessary to sufficiently increase a distance between the ink jet head and the electrical component mounting board 1000. In such a case, the jet of ink is likely to be affected by disturbance between the ink jet head and the electrical component mounting board 1000, so that the conductive pattern 1200 is likely to be disturbed.

Furthermore, the generation of a jet timing of the ink jet head is corrected using a signal or the like of an encoder provided in a relative movement mechanism, but an error may occur in the jet timing of the ink jet head. In particular, in a case where a relative movement speed is relatively high, an error is likely to occur in the jet timing of the ink jet head.

Moreover, although the shape of misregistration is different from that of the conductive pattern 1200 shown in FIG. 4, errors may occur in the formation positions of the dots 1202 even in a direction orthogonal to the relative movement direction. For example, in a case where the board is moved relative to the ink jet head of which the position is fixed, the board may meander. In a case where the movement speed of the board is relatively high, an influence of the meandering of the board is likely to appear in the conductive pattern 1200.

FIG. 5 is a schematic diagram of a pattern in a case where satellites are generated. In a case where a distance between the board and the ink jet head is relatively long so that the conductive pattern 1200 is printed on the electrical component mounting board 1000 shown in FIG. 1, the risk of generation of satellites is increased. In a case where satellites are generated, the satellites land at a position away from the conductive pattern 1200 and satellite dots 1206 are formed. There is a concern that the satellite dots 1206 may be formed in a region to which the conductive ink should not originally adhere.

### [Method of Manufacturing Pattern-Formed Board According to Embodiment]

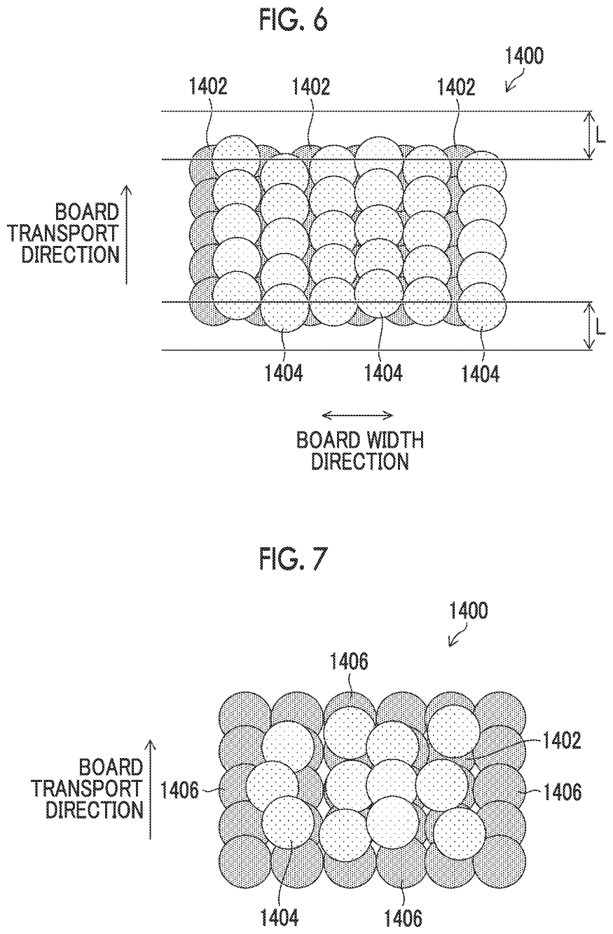

FIG. 6 is a schematic diagram of a pattern that is formed using the method of manufacturing a pattern-formed board according to the embodiment. The embodiment to be described below shows an example of printing performed by a single-pass method using a line-type ink jet head. The single-pass method is a method of moving the board and the ink jet head relative to each other once to form a prescribed pattern over the entire surface of the board.

Further, in the method of manufacturing a pattern-formed board according to the present embodiment, a plurality of times of relative movement are performed and ink is jetted during each relative movement to form a pattern having a prescribed thickness.

Here, a plurality of nozzles are disposed in the line-type ink jet head over the entire length of the ink jet head in a direction orthogonal to the relative movement direction. An aspect of a relative movement in which the board is moved relative to the ink jet head of which the position is fixed is shown in the present embodiment. The transport direction of the board will be referred to as a board transport direction, and a direction orthogonal to the board transport direction will be referred to as a board width direction.

The term “orthogonal” described in the present specification may include the term “substantially orthogonal” from which the same effects as those in a case where an angle between two directions is 90° are obtained even in a case where an angle between two directions is less than 90° or a case where an angle between two directions exceeds 90°.

In the method of manufacturing a pattern-formed board according to the embodiment, a relative movement speed applied to a first relative movement among the plurality of times of the relative movement between the electrical component mounting board 1000 and the ink jet head is set to be lower than a relative movement speed applied to a second or subsequent relative movement. A relative movement speed set to the second or subsequent relative movement may be an arithmetic average of relative movement speeds set for the respective times of the second relative movement.

In a case where the respective relative movement speeds of the plurality of times of the relative movement are compared with each other, a minimum value among the respective relative movement speeds of the plurality of times of the relative movement may be applied as a relative movement speed applied to the first relative movement.

Here, a relative movement of which the number of times is determined, such as the first relative movement and the second relative movement, is a relative movement in which ink used to print a conductive pattern is jetted from the ink jet head, and the number of times of relative movement in which the conductive ink is not jetted from the ink jet head may not be counted. Further, in a case where the conductive ink not contributing to a conductive pattern is jetted even though the conductive ink is jetted from the ink jet head, the number of times of relative movement may not be counted.

For example, it is preferable that all of “V₁<V₂”, “V₁<V₃”, “V₁<V₄”, and “V₁<V₅” are satisfied in a case where the relative movement is performed five times, the conductive ink is jetted from the ink jet head during each relative movement, and relative movement speeds applied to the first to fifth relative movements are denoted by V₁, V₂, V₃, V₄, and V₅.

The right side of each of the inequalities may be (V₂+V₃+V₄+V₅)/4. The V₂, V₃, V₄, and V₅ may be equal to each other or different from each other. A relative magnitude relationship between V₂, V₃, V₄, and V₅ may be defined on the basis of the viewpoint of productivity.

A conductive pattern 1400 shown in FIG. 6 has a structure in which dots 1404 formed using liquid jetted to positions in contact with dots 1402, which are formed in the jet of the liquid during the first relative movement, in the jet of the liquid during the second relative movement overlap with the dots 1402.

In the conductive pattern 1400 shown in FIG. 6, the landing positions of the dots 1402 formed in a case where the liquid is jetted during the first relative movement are less shifted than those in a case where the relative movement speed is relatively high. Further, in a case where the electrical component mounting board 1000 and the ink jet head are relatively slowly moved relative to each other, satellites and main droplets can be caused to land on the board without the separation of the satellites from the main droplets even though the satellites are generated during jet.

Then, the dots 1404, which are the conductive ink having landed on the electrical component mounting board 1000 in the jet of the liquid during the second relative movement, are attracted to the dots 1402 that are printed on the electrical component mounting board 1000 in the jet of the liquid during the first relative movement. In such a case, the dots 1404 formed in the jet of the liquid during the second relative movement are overwritten on a pattern that is formed of the dots 1402 disposed at a high accuracy and formed in the jet of the liquid during the first relative movement. In such a case, even though the relative movement is performed a plurality of times, the same printing position accuracy as the jet of the liquid during the first relative movement can be ensured in the jet of the liquid during the second or subsequent relative movement.

A case where two times of relative movement are performed has been described here. However, in a case where three or more times of the relative movement are performed to form a conductive pattern, the printing position accuracy of dots formed in the jet of liquid during the third or subsequent relative movement is also ensured as with the dots 1404 formed in the jet of the liquid during the second relative movement.

An aggregate of the dots 1402 formed in the jet of the liquid during the first relative movement disclosed in the embodiment is an example of a first pattern element, and an aggregate of the dots 1404 formed in the jet of the liquid during the second relative movement is an example of a second pattern element.

The boundary positions of the conductive pattern 1400 may be a region of one dot or more, and are defined in consideration of the productivity of the conductive pattern 1400. The boundary positions of the conductive pattern 1400 preferably correspond to five dots or less and more preferably correspond to three dots or less.

The boundary positions of the conductive pattern 1400 mentioned here mean boundary positions between the conductive pattern 1400 and the electrical component mounting board 1000. The boundary positions of the conductive pattern 1400 are synonymous with edges of the conductive pattern 1400, ends of the conductive pattern 1400, a periphery of the conductive pattern 1400, and the like.

### [Jetting Frequency]

In a case where a relative movement speed is relatively reduced without a change in printing resolution, the volume of the conductive ink jetted from the ink jet head per unit time is relatively reduced and productivity falls. Accordingly, even in a case where a relative movement speed is relatively reduced without a change in printing resolution, the same jetting frequency as in a case where the relative movement speed is not reduced is applied. That is, the same jetting frequency as a jetting frequency applied to the jet of the liquid during the second or subsequent relative movement is applied to the first relative movement. The jet of the conductive ink in the jet of the liquid during the first relative movement has higher printing resolution in the relative movement direction than the jet of the liquid during the second or subsequent relative movement. For example, in a case where a relative movement speed is set to ½ times, printing resolution in the relative movement direction is doubled.

Accordingly, the conductive ink can be jetted during the first relative movement without a change in a jet volume per unit time in the jet of the liquid during the first relative movement with respect to an average jet volume of the conductive ink per unit time in the jet of the liquid during the second or subsequent relative movement.

### [With Regard to Relative Movement Speed Ratio]

It is preferable that a relative movement speed applied to the first relative movement is ¾ times or less a relative movement speed of the second or subsequent relative movement. Accordingly, the disturbance of the conductive pattern printed on the board can be significantly suppressed during the first relative movement.

### [Type of Liquid Droplets]

In order to improve the printing position accuracy of the conductive pattern in the first relative movement, a type of liquid droplets in which satellites are least likely to be generated may be selected among a plurality of types of liquid droplets having volumes different from each other. The case of generation of satellites for each type of liquid droplets can be ascertained from the actual jet of the conductive ink to the electrical component mounting board 1000. In a case where a small number of nozzles, such as one nozzle, are used to ascertain the case of generation of satellites for each type of liquid droplets, there may be a risk that it is difficult to verify variations in jetting characteristics of each nozzle. Accordingly, a plurality of nozzles of which the number is equal to or larger than a certain number, such as 100 nozzles, are used to jet the conductive ink and nozzles in which satellites have been generated are counted or the like, so that a difficulty in generating satellites for each type of liquid droplets can be evaluated.

Here, in a case where the case of generation of satellites is to be ascertained, a distance between the ink jet head and the electrical component mounting board 1000 can be increased to facilitate the determination of the case of generation of satellites. Likewise, the relative movement speed may be relatively increased.

In general, as the size of a liquid droplet is smaller, satellites are less likely to be generated. Accordingly, in order to improve the printing position accuracy of the conductive pattern in the jet of the liquid during the first relative movement, a type of liquid droplets having the smallest size may be selected among a plurality of types of liquid droplets. The type of liquid droplets disclosed in the embodiment is an example of a liquid droplet size.

### [Formation of Boundary Dots of Conductive Pattern]

FIG. 7 is a schematic diagram showing the formation of boundary dots. In a conductive pattern 1400 shown in FIG. 7, dark dot hatching is added to dots 1402 formed in the jet of the liquid during the first relative movement and light dot hatching is added to dots 1404 formed in the jet of the liquid during the second relative movement.

The dots 1402 formed in the jet of the liquid during the first relative movement include boundary dots 1406 that form boundary positions of the conductive pattern 1400. On the other hand, the dots 1404 formed in the jet of the liquid during the second relative movement do not include the boundary dots 1406 and are disposed at non-boundary positions that are positions inside the conductive pattern 1400. That is, printing for forming the boundary dots 1406 is not performed in the jet of the liquid during the second relative movement.

Accordingly, the boundary dots 1406 are formed and printing position accuracy required for the boundary positions of the conductive pattern 1400 is ensured in the jet of the liquid during the first relative movement where constant printing position accuracy is ensured. In such a case, even though the jet state of the ink jet head deteriorates in the jet of the liquid during the second relative movement, a risk that the conductive pattern 1400 protrudes from the allowable range L of the printing position accuracy is reduced. That is, even in a case where the dots 1404 formed in the jet of the liquid during the second relative movement land on the board while having misregistration, the printing position accuracy of the conductive pattern 1400 is not affected.

### [Drive Voltage Waveform]

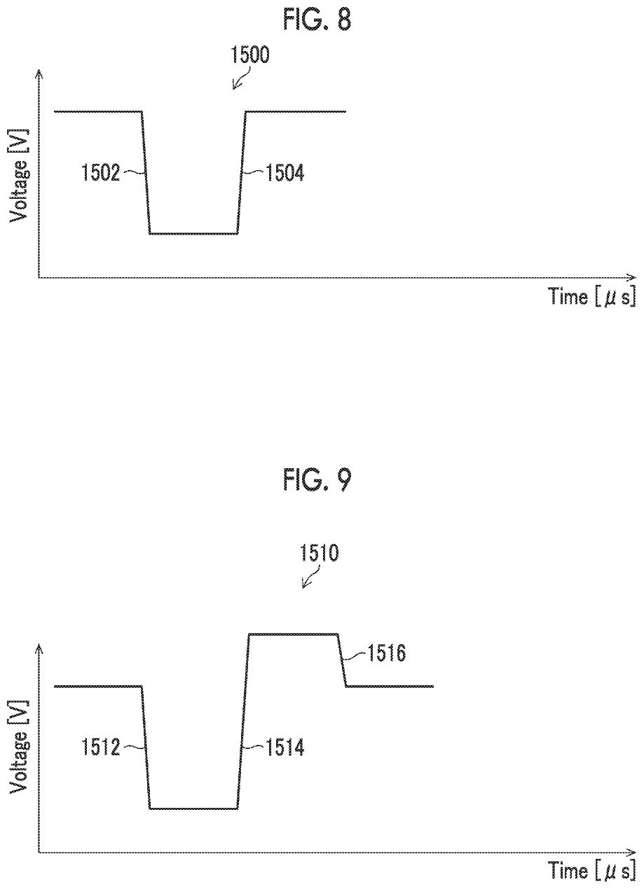

FIG. 8 is a waveform diagram showing a first example of a drive voltage waveform. In FIG. 8, a drive voltage waveform is represented using a graph format in which a horizontal axis is a time axis and a vertical axis is a voltage axis. The same applies to FIGS. 9 to 12.

In order to relatively improve the printing position accuracy of the conductive pattern 1400, it is preferable that liquid droplets likely to be most simply jetted by the ink jet head are used. Accordingly, a jet using a single-pulse drive voltage waveform is preferable in a case of a piezoelectric method of generating pressure, which contributes to a jet, using the deflection deformation of a piezoelectric element. Specifically, a drive voltage waveform 1500 shown in FIG. 8 includes a waveform element 1502 for pulling the piezoelectric element and a waveform element 1504 for pushing the piezoelectric element, and is formed of only one pulse contributing to a jet.

FIG. 9 is a waveform diagram showing a second example of a drive voltage waveform. A drive voltage waveform 1510 shown in FIG. 9 includes a waveform element 1512 for pulling the piezoelectric element, a waveform element 1514 for pushing the piezoelectric element, and a waveform element 1516 for pulling the piezoelectric element after pushing the piezoelectric element. In the drive voltage waveform 1510, one pulse including the waveform element 1512 and the waveform element 1514 contributes to a jet. The waveform element 1516 has a function to stabilize a meniscus after liquid droplets are jetted.

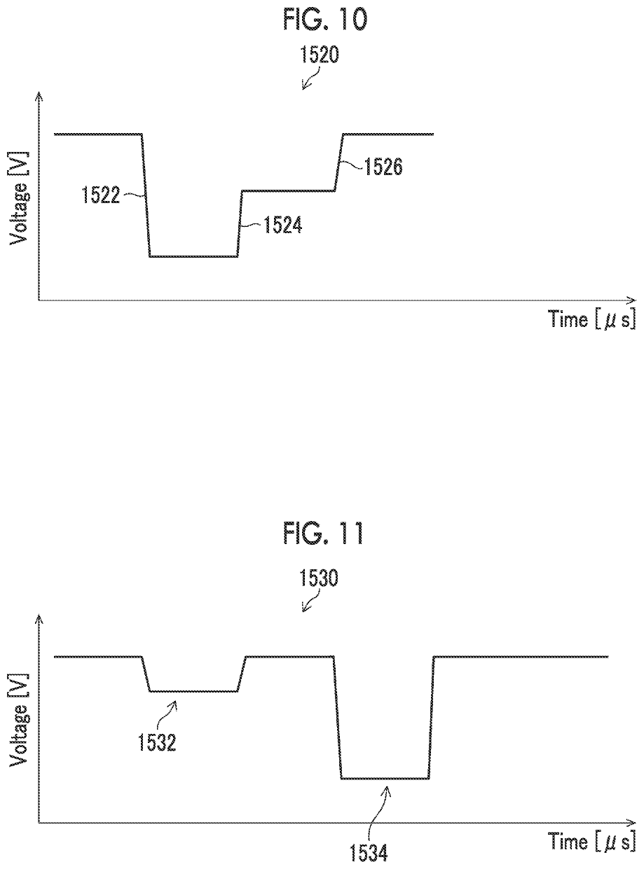

FIG. 10 is a waveform diagram showing a third example of a drive voltage waveform. A drive voltage waveform 1520 shown in FIG. 10 includes a waveform element 1522 for pulling the piezoelectric element, a waveform element 1524 for pushing the piezoelectric element, and a waveform element 1526 for pushing the piezoelectric element after pushing the piezoelectric element. In the drive voltage waveform 1520, one pulse including the waveform element 1522, the waveform element 1524, and the waveform element 1526 contributes to a jet.

FIG. 11 is a waveform diagram showing a fourth example of a drive voltage waveform. A drive voltage waveform 1530 shown in FIG. 11 includes a first pulse 1532 that does not contribute to a jet and a second pulse 1534 that contributes to a jet. The first pulse 1532 that does not contribute to a jet adds momentum in a jet direction to the ink to be jetted before the second pulse that contributes to a jet is applied.

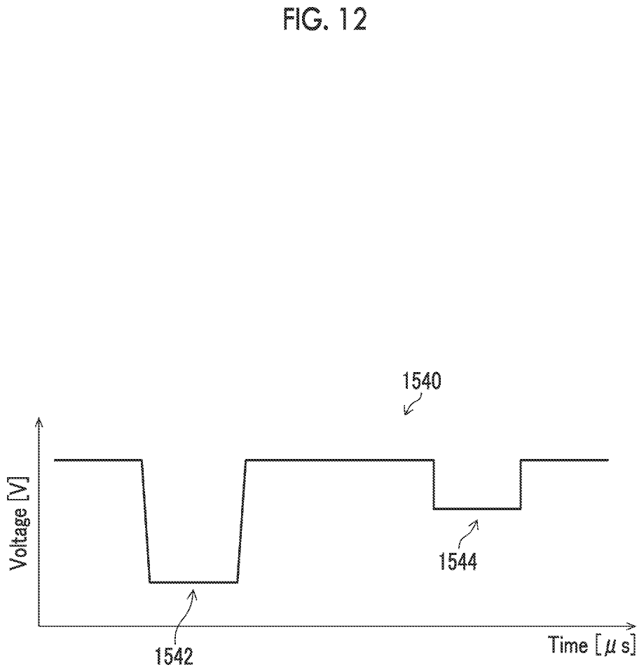

FIG. 12 is a waveform diagram showing a fifth example of a drive voltage waveform. A drive voltage waveform 1540 shown in FIG. 12 includes a first pulse 1542 that contributes to a jet and a second pulse 1544 that does not contribute to a jet. The second pulse 1544 that does not contribute to a jet is a damping pulse for controlling the vibration of a meniscus after jetting the ink. A drive voltage having the drive voltage waveform disclosed in the embodiment is an example of a drive voltage that includes one pulse-shaped voltage.

### [Distance Between Ink Jet Head and Board]

In the first relative movement of which the relative movement speed is reduced as compared to the relative movement speed of the second or subsequent relative movement, a distance between the ink jet head and the board may be set to be shorter than that in the second or subsequent relative movement. In the first relative movement, certain transport stability of the board is ensured and a risk of collision between the ink jet head and the board or between the ink jet head and an electrical component mounted on the board is reduced.

Further, in a case where a sensor used to prevent collision between the ink jet head and the board is provided and an abnormality is detected, the relative movement is stopped. A braking distance required to stop the relative movement in a case where an abnormality is detected can be shorter as the relative movement speed is lower.

Although the conductive pattern formed using the conductive ink has been exemplified in the present embodiment, the method of manufacturing a pattern-formed board according to the present embodiment can also be applied to functional patterns formed using ink having various functions, such as an insulating pattern formed using insulating ink.

### [Procedure of Method of Manufacturing Pattern-Formed Board]

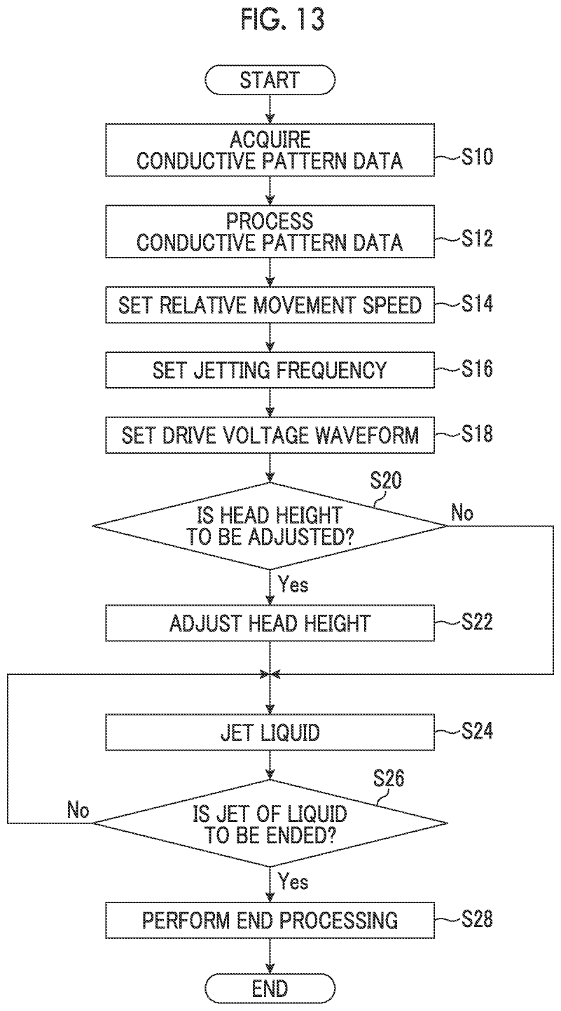

FIG. 13 is a flowchart showing a procedure of the method of manufacturing a pattern-formed board according to the embodiment. A control device of a liquid jet apparatus to which a computer is applied executes various programs, so that the flowchart shown in FIG. 13 is performed.

In a conductive pattern data acquisition step S10, conductive pattern data are acquired. Data indicating the position of the conductive pattern 1020 on the printed wiring board 1002 are applied as the conductive pattern data. After the conductive pattern data acquisition step S10, processing proceeds to a conductive pattern data processing step S12.

In the conductive pattern data processing step S12, signal processing, such as halftone processing, is performed on the conductive pattern data acquired in the conductive pattern data acquisition step S10 and halftone data in which the arrangement of dots and the size of the dot in the conductive pattern are defined are generated.

A halftone processing rule in which a type of liquid droplets, in which satellites are less likely to be generated in the jet of the liquid during the first relative movement, is selected can be applied in the conductive pattern data processing step S12. A type of liquid droplets having the smallest size can be selected as the type of liquid droplets in which satellites are less likely to be generated.

That is, halftone processing applied to the jet of the liquid during the first relative movement and halftone processing applied to the jet of the liquid during the second or subsequent relative movement may be changed in the conductive pattern data processing step S12. After the conductive pattern data processing step S12, the processing proceeds to a relative movement speed setting step S14.

Relative movement speeds applied to a plurality of times of the relative movement are set in the relative movement speed setting step S14. In the relative movement speed setting step S14, a ratio of the relative movement speed of the first relative movement to an average of the relative movement speed of the second or subsequent relative movement may be set as the relative movement speed of the first relative movement. After the relative movement speed setting step S14, the processing proceeds to a jetting frequency setting step S16.

A jetting frequency of the ink jet head applied to the jet of the liquid during each of the plurality of times of the relative movement is set in the jetting frequency setting step S16. In the jetting frequency setting step S16, a ratio of the jetting frequency applied to the jet of the liquid during the first relative movement to the jetting frequency applied to the jet of the liquid during the second or subsequent relative movement may be set as the jetting frequency applied to the jet of the liquid during the first relative movement, on the basis of a ratio of the relative movement speed applied to the first relative movement to an average of the relative movement speed applied to the second or subsequent relative movement. After the jetting frequency setting step S16, the processing proceeds to a drive voltage waveform setting step S18.

A drive voltage waveform applied to the jet of the liquid during each of the plurality of times of the relative movement is set in the drive voltage waveform setting step S18. A drive voltage waveform in which the generation of satellites during the jet is suppressed is set as the drive voltage waveform applied to the jet of the liquid during the first relative movement. As the drive voltage waveform applied to the jet of the liquid during the second or subsequent relative movement, the drive voltage waveform applied to the jet of the liquid during the first relative movement may be set or any drive voltage waveform may be set. After the drive voltage waveform setting step S18, the processing proceeds to a head height adjustment determination step S20.

Whether or not to adjust a head height in the first relative movement is determined in the head height adjustment determination step S20. Here, the head height is a distance between the ink jet head and the board.

In a case where it is determined not to adjust the head height in the head height adjustment determination step S20, a determination result is No. In a case where a determination result is No, the head height is not adjusted and the processing proceeds to a liquid jet step S24. On the other hand, in a case where it is determined to adjust the head height in the head height adjustment determination step S20, a determination result is Yes. In a case where a determination result is Yes, the processing proceeds to a head height adjustment step S22.

The head height is adjusted using a head lifting device before the first relative movement is performed in the head height adjustment step S22. After the head height adjustment step S22, the processing proceeds to the liquid jet step S24.

In the liquid jet step S24, the relative movement between the board and the ink jet head is performed a plurality of times and an overwritten conductive pattern is printed on the board. In a case where the head height is adjusted before the first relative movement is performed in the head height adjustment step S22, the head height returns to the original setting before the second relative movement is performed in the liquid jet step S24.

In a case where the jet of the liquid is started in the liquid jet step S24, the processing proceeds to a liquid jet end determination step S26. Then, whether or not to end the liquid jet step S24 is determined in the liquid jet end determination step S26.

That is, whether or not a condition for ending the liquid jet step S24 is satisfied is determined in the liquid jet end determination step S26. An example of the condition for ending the liquid jet step S24 includes an end of the formation of the conductive pattern 1020. Another example of the condition for ending the liquid jet step S24 includes the acquisition of a signal indicating the end of the liquid jet step S24.

In a case where it is determined to continue the liquid jet step S24 in the liquid jet end determination step S26, a determination result is No. In a case where a determination result is No, the liquid jet step S24 is continued. On the other hand, in a case where it is determined to end the liquid jet step S24 in the liquid jet end determination step S26, a determination result is Yes. In a case where a determination result is Yes, the processing proceeds to an end processing step S28.

In the end processing step S28, prescribed end processing is performed and the procedure of the method of manufacturing a pattern-formed board is ended. Whether or not to manufacture the next pattern-formed board is determined in the end processing step S28. In a case where it is determined to manufacture the next pattern-formed board, the respective steps from the conductive pattern data acquisition step S10 to the end processing step S28 may be performed.

The respective steps shown in FIG. 13 can be integrated, separated, and omitted as appropriate. Further, steps not shown in FIG. 13 may be appropriately added to the procedure of the method of manufacturing a pattern-formed board. For example, determination steps of determining whether or not various parameters need to be set or changed may be included before the steps of setting various parameters.

Further, information about the type of a board to be processed may be acquired and various parameters may be automatically set depending on the type of the board to be processed. Examples of the type of the board to be processed include an electrical component mounting board on which electrical components are mounted, a printed wiring board on which electrical components are not yet mounted, and the like.

### [Configuration Example of Liquid Jet Apparatus]

Next, a liquid jet apparatus comprising an ink jet head, which is a liquid jet head using an ink jet method, will be described as a device that realizes the method of manufacturing a pattern-formed board described with reference to FIGS. 1 to 13. The liquid jet apparatus to be described below can be configured as a liquid jet system of which components are dispersedly disposed.

### [Overall Configuration]

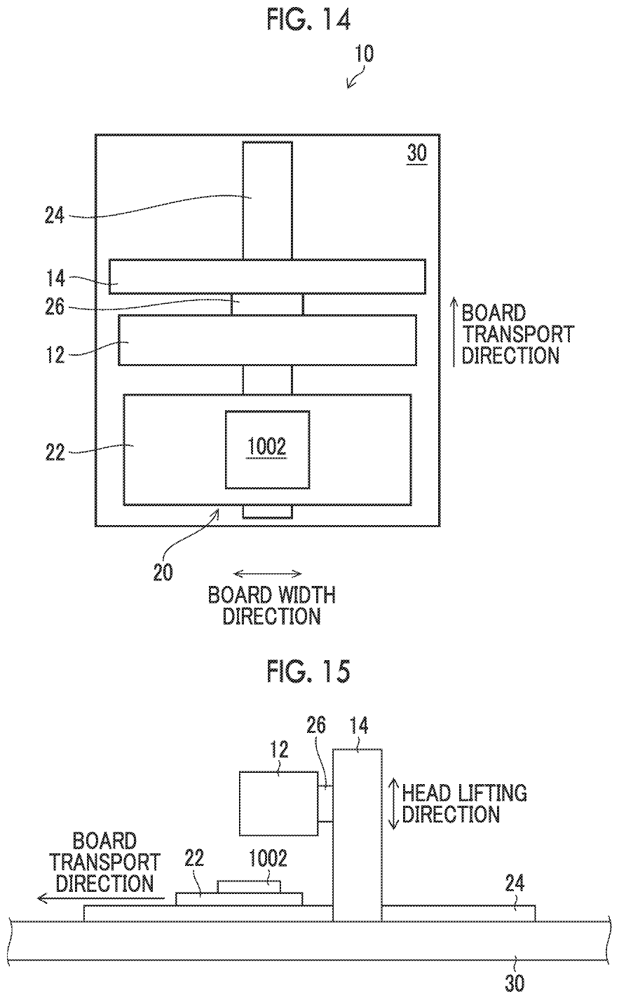

FIG. 14 is a diagram showing the overall configuration of a liquid jet apparatus according to an embodiment. The liquid jet apparatus 10 shown in FIG. 14 comprises an ink jet head 12, a head support member 14, a transport device 20, and a base 30. The ink jet head 12 and the transport device 20 are disposed on an upper surface of the base 30 as which a surface plate or the like is applied.

The head support member 14 is formed of two pillars that stand on the base 30 and a head support column of which both ends are supported by the two pillars. A head lifting device 26 that lifts and lowers the ink jet head 12 is mounted on the head support member 14. The ink jet head 12 is connected to the head lifting device 26, and is supported to be freely lifted and lowered by the head support member 14. Detailed structures of the head support member 14 and the head lifting device 26 are not shown in FIG. 14.

A line-type head in which a plurality of nozzles are arranged along a length exceeding the entire width of the printed wiring board 1002 in the board width direction is applied as the ink jet head 12. The liquid jet apparatus 10 comprising the line-type head can jet the liquid using a single-pass method that can apply conductive ink to the entire surface of the printed wiring board 1002 by causing the ink jet head 12 to scan the printed wiring board 1002 once. The ink jet head may be formed of a combination of a plurality of head modules.

Two-dimensional arrangement can be applied as the arrangement of the nozzles of the ink jet head 12. Zigzag arrangement or matrix arrangement of two rows can be applied as an example of the two-dimensional arrangement. Nozzle openings are arranged on a nozzle surface of the ink jet head 12 corresponding to the arrangement of the nozzles. The ink jet head 12 jets conductive ink from each of the plurality of nozzle openings arranged on the nozzle surface.

A piezoelectric method of pressurizing conductive ink using the deflection deformation of a piezoelectric element to jet the conductive ink can be applied as a jet method of the ink jet head 12. A thermal method of heating conductive ink using a heater and jetting the conductive ink using a film boiling phenomenon of the conductive ink can be applied as the jet method of the ink jet head 12.

The liquid jet apparatus 10 comprises the transport device 20 that transports the printed wiring board 1002 in the board transport direction. The transport device 20 comprises a table 22 that supports the printed wiring board 1002 and a board moving mechanism 24 that moves the table 22 in the board transport direction.

The table 22 comprises a fixing mechanism that fixes the printed wiring board 1002. An aspect in which the printed wiring board 1002 is mechanically fixed may be applied to the fixing mechanism, or an aspect in which negative pressure is applied to the printed wiring board 1002 to attract the printed wiring board 1002 may be applied to the fixing mechanism.

The table 22 may comprise a height adjustment mechanism that finely adjusts a distance between the printed wiring board 1002 and the ink jet head 12. The table 22 may be adapted to freely adjust the position of the printed wiring board 1002 in the board width direction.

An aspect in which a ball screw drive mechanism, a belt drive mechanism, or the like is connected to a rotating shaft of a motor can be applied to the board moving mechanism 24. An aspect in which a linear motor is provided may be applied to the board moving mechanism 24.

Although an aspect in which the printed wiring board 1002 is moved in the board transport direction relative to the ink jet head 12 of which the position in the board transport direction is fixed has been described in the present embodiment, the ink jet head 12 may be moved in the board transport direction relative to the printed wiring board 1002 of which the position in the board transport direction is fixed. Further, both the printed wiring board 1002 and the ink jet head 12 may be moved in the board transport direction. The board moving mechanism 24 disclosed in the embodiment is an example of a moving device that moves the board and the liquid jet head relative to each other.

The liquid jet apparatus 10 may comprise a short ink jet head shorter than the entire length of the printed wiring board 1002 in the board width direction, and a serial method of moving the printed wiring board 1002 and the ink jet head relative to each other in both the board width direction and the board transport direction to print a conductive pattern over the entire surface of the printed wiring board 1002 may be applied to the liquid jet apparatus 10.

FIG. 15 is a schematic diagram of a lifting mechanism of the liquid jet apparatus shown in FIG. 14. FIG. 15 is a diagram showing the liquid jet apparatus 10 as viewed in the board width direction, and corresponds to a front view of the liquid jet apparatus 10 in a case where a plan view of the liquid jet apparatus 10 is used.

The head lifting device 26 moves the position of the ink jet head 12 in a head lifting direction that is a direction orthogonal to the board transport direction and is orthogonal to the board width direction. A linear moving member, such as a ball screw drive mechanism or a linear motor, is applied to the head lifting device 26. The linear moving member is disposed in parallel to the head lifting direction. The head lifting device 26 disclosed in the embodiment is an example of a change device that changes a distance between the board and a liquid jet head.

### [Electrical Configuration of Liquid Jet Apparatus]

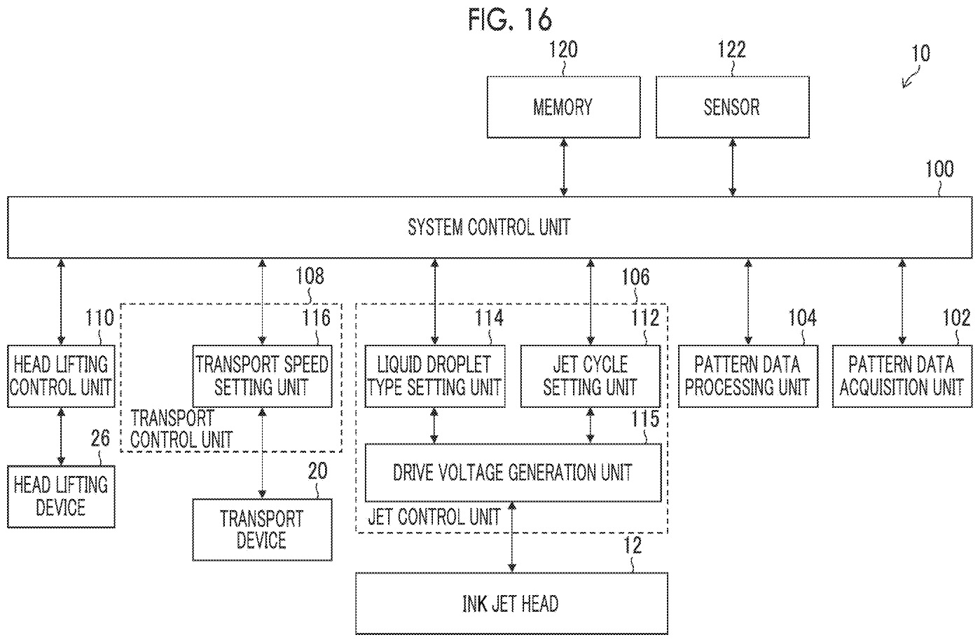

FIG. 16 is a functional block diagram showing an electrical configuration of the liquid jet apparatus shown in FIG. 14. The liquid jet apparatus 10 comprises a system control unit 100, a pattern data acquisition unit 102, a pattern data processing unit 104, a jet control unit 106, a transport control unit 108, and a head lifting control unit 110.

The system control unit 100 transmits command signals to the pattern data acquisition unit 102, the pattern data processing unit 104, the jet control unit 106, the transport control unit 108, and the head lifting control unit 110 to collectively control the operation of the liquid jet apparatus 10.

The pattern data acquisition unit 102 acquires pattern data of a conductive pattern from an external device, such as a host computer. That is, the pattern data acquisition unit 102 acquires the pattern data of liquid to be jet using the ink jet head 12.

The pattern data processing unit 104 performs processing on the pattern data, which are acquired by the pattern data acquisition unit 102, in response to the command signal transmitted from the system control unit 100. The pattern data processing unit 104 can generate halftone data of conductive ink from the pattern data of the conductive pattern. The pattern data processing unit 104 transmits the halftone data of the conductive ink to the jet control unit 106.

The jet control unit 106 controls the jet of the ink from the ink jet head 12 on the basis of the command signal transmitted from the system control unit 100. The jet control unit 106 comprises a jet cycle setting unit 112, a liquid droplet type setting unit 114, and a drive voltage generation unit 115.

The jet cycle setting unit 112 sets a jetting frequency to be applied to the ink jet head 12. Specifically, the jet cycle setting unit 112 can set the same jetting frequency as a jetting frequency, which is applied to the jet of the liquid during the second or subsequent relative movement, for the jet of the liquid during the first relative movement. The jetting frequency disclosed in the embodiment is an example of a driving frequency.

The liquid droplet type setting unit 114 sets a type of liquid droplets, in which satellites are less likely to be generated, as a type of liquid droplets that are applied to the jet of the liquid during the first relative movement. The liquid droplet type setting unit 114 can select and set a type of liquid droplets, in which satellites are less likely to be generates, with reference to a table or the like in which a type of liquid droplets in which satellites of the conductive ink or the like are less likely to be generated is stored. The liquid droplet type setting unit 114 may be included in the pattern data processing unit 104.

The drive voltage generation unit 115 generates a drive voltage that is to be supplied to a piezoelectric element provided in the ink jet head 12, and supplies the drive voltage to the piezoelectric element. The drive voltage generation unit 115 can use a drive voltage waveform, which includes one pulse contributing to one jet, as a drive voltage waveform, which is applied to the jet of the liquid during the first relative movement, to generate the drive voltage. The jet control unit 106 disclosed in the embodiment is an example of a head drive unit that drives the liquid jet head.

The transport control unit 108 controls the operation of the transport device 20 on the basis of the command signal that is transmitted from the system control unit 100. The transport control unit 108 comprises a transport speed setting unit 116. The transport speed setting unit 116 controls the relative movement speed of each relative movement during the plurality of times of the relative movement.

Specifically, the transport control unit 108 sets a relative movement speed, which is lower than the relative movement speed of the printed wiring board 1002 to be applied to the second or subsequent relative movement, for the first relative movement.

The head lifting control unit 110 controls the operation of the head lifting device 26 on the basis of the command signal that is transmitted from the system control unit 100. The head lifting control unit 110 can adjust the position of the ink jet head in the head lifting direction according to the number of times of the relative movement.

The liquid jet apparatus 10 comprises a memory 120. Various data, various parameters, various programs, and the like used for the control of the liquid jet apparatus 10 are stored in the memory 120. The system control unit 100 applies various parameters and the like, which are stored in the memory 120, to control each part of the liquid jet apparatus 10.

The liquid jet apparatus 10 comprises a sensor 122. The sensor 122 shown in FIG. 16 includes various sensors provided in the liquid jet apparatus 10, such as a sensor for preventing collision between the ink jet head 12 and the electrical component mounting board 1000, a temperature sensor, and a position detection sensor. Various processing units shown in FIG. 16 are categorized according to functions for convenience, and can be appropriately integrated, separated, changed, deleted, added, or the like.

### [Configuration of Hardware of Liquid Jet Apparatus]

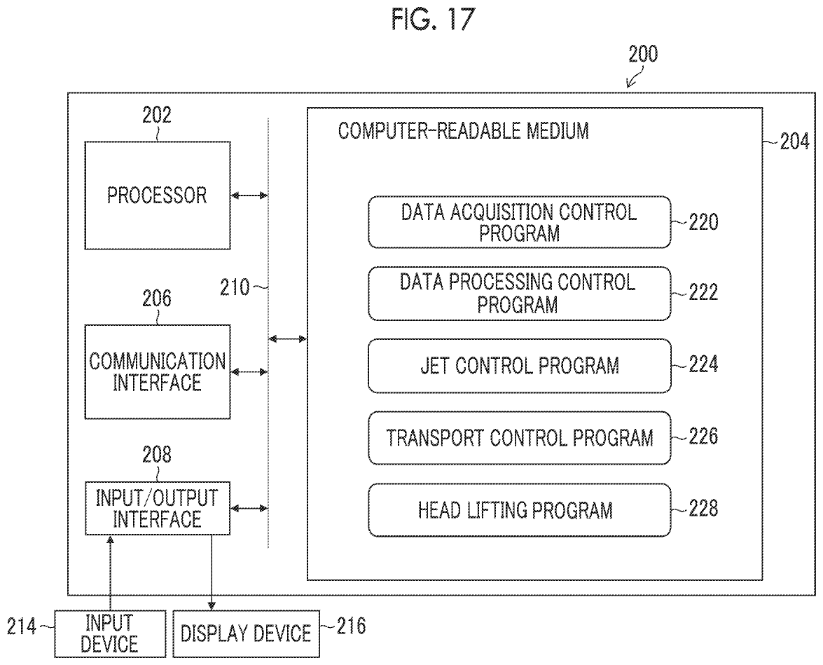

FIG. 17 is a block diagram showing a configuration example of the hardware of the liquid jet apparatus shown in FIG. 14. A control device 200 provided in the liquid jet apparatus 10 comprises a processor 202, a computer-readable medium 204 that is a non-transitory tangible object, a communication interface 206, and an input/output interface 208.

A computer is applied as the control device 200. A form of the computer may be a server, a personal computer, a workstation, a tablet terminal, and the like.

The processor 202 comprises a central processing unit (CPU) that is a general-purpose processing device. The processor 202 may comprise a graphics processing unit (GPU) that is a processing device specialized for image processing.

The processor 202 is connected to the computer-readable medium 204, the communication interface 206, and the input/output interface 208 via a bus 210. An input device 214 and a display device 216 are connected to the bus 210 via the input/output interface 208.

The computer-readable medium 204 comprises a memory that is a main memory and a storage that is an auxiliary memory. A semiconductor memory, a hard disk device, a solid state drive device, and the like can be used as the computer-readable medium 204. Any combination of a plurality of devices can be used as the computer-readable medium 204.

The hard disk device can be referred to as an HDD that is an abbreviation for Hard Disk Drive in English. The solid state drive device can be referred to as an SSD that is an abbreviation for Solid State Drive in English.

The control device 200 is connected to a network via the communication interface 206, and is connected to an external device to be capable of communicating with the external device. A local area network (LAN) and the like can be used as the network. The network is not shown.

A data acquisition control program 220, a data processing control program 222, a jet control program 224, a transport control program 226, and a head lifting program 228 are stored in the computer-readable medium 204. The computer-readable medium 204 can function as the memory 120 shown in FIG. 16.

The data acquisition control program 220 corresponds to a control to acquire various data that are applied to the pattern data acquisition unit 102 shown in FIG. 16. The data processing control program 222 corresponds to processing of various data that are applied to the ink jet head 12. The jet control program 224 corresponds to a jet control that is applied to the ink jet head 12. The transport control program 226 corresponds to the transport control of the printed wiring board 1002 that is applied to the transport device 20. The head lifting program 228 corresponds to a head lifting control that is applied to the head lifting device 26.

Various programs stored in the computer-readable medium 204 include one or more commands. Various data, various parameters, and the like are stored in the computer-readable medium 204.

In the liquid jet apparatus 10, the processor 202 executes the various programs stored in the computer-readable medium 204 to realize various functions of the liquid jet apparatus 10. The term “program” is synonymous with the term “software”.

The control device 200 performs data communication with an external device via the communication interface 206. Various standards, such as universal serial bus (USB), can be applied to the communication interface 206. Either wired communication or wireless communication may be applied as a communication form of the communication interface 206.

The input device 214 and the display device 216 are connected to the control device 200 via the input/output interface 208. An input device, such as a keyboard or a mouse, is applied as the input device 214. Various types of information applied to the control device 200 are displayed on the display device 216.

A liquid crystal display, an organic EL display, a projector, and the like can be applied as the display device 216. Any combination of a plurality of devices can be applied as the display device 216. The term “EL” of an organic EL display is an abbreviation for Electro-Luminescence.

Here, examples of a hardware structure of the processor 202 include a CPU, a GPU, a programmable logic device (PLD), and an application specific integrated circuit (ASIC). The CPU is a general-purpose processor that executes a program and acts as various functional units. The GPU is a processor specialized for image processing.

The PLD is a processor of which a configuration of an electrical circuit can be changed after the manufacture of a device. Examples of the PLD include a field programmable gate array (FPGA). The ASIC is a processor that comprises a dedicated electrical circuit specifically designed to perform specific processing.

One processing unit may be formed of one of these various processors, or may be formed of two or more processors of the same type or different types. Examples of a combination of the various processors include a combination of one or more FPGAs and one or more CPUs, and a combination of one or more FPGAs and one or more GPUs. Other examples of a combination of the various processors include a combination of one or more CPUs and one or more GPUs.

A plurality of functional units may be formed using one processor. As an example in which a plurality of functional units are configured using one processor, there is an aspect in which a combination of one or more CPUs and software, such as system on a chip (SoC) represented by a computer, such as a client or a server, is applied to form one processor and this processor is made to act as the plurality of functional units.

As another example in which a plurality of functional units are configured using one processor, there is an aspect in which a processor that realizes the functions of the entire system including the plurality of functional units with one IC chip is used.

As described above, various functional units are configured using one or more of the various processors described above as the hardware structure. Further, the hardware structure of the various processors described above is, more specifically, an electrical circuit (circuitry) in which circuit elements, such as semiconductor elements, are combined.

The computer-readable medium 204 may include semiconductor elements, such as a read only memory (ROM) and a random access memory (RAM). The computer-readable medium 204 may include a magnetic storage medium, such as a hard disk. The computer-readable medium 204 may include a plurality of types of storage mediums.

Although the jet of the liquid using an ink jet method has been exemplified for the formation of the conductive pattern 1020 in the present embodiment, various liquid coating methods, such as a dispenser method and a spray method, may be applied for the formation of the conductive pattern 1020 and the like.

### [Effects of Embodiment]

The following effects can be obtained from a method of manufacturing an electrical component mounting board, a liquid jet apparatus, and an electrical component mounting board according to embodiments.

[1]

In a case where a relative movement between an electrical component mounting board 1000 and an ink jet head 12 is performed a plurality of times to form a conductive pattern 1020 on the electrical component mounting board 1000, a relative movement speed, which is lower than a relative movement speed applied to the second or subsequent relative movement, is set for the first relative movement.

Accordingly, required printing position accuracy can be ensured in a conductive pattern formed in the jet of liquid during the first relative movement. Since ink droplets forming a conductive pattern formed in the jet of the liquid during the second or subsequent relative movement are attracted to the conductive pattern formed previously, printing position accuracy equivalent to the printing position accuracy of the conductive pattern formed in the jet of the liquid during the first relative movement can be ensured even in the conductive pattern formed in the jet of the liquid during the second or subsequent relative movement.

Further, even though satellites are generated in a case where main droplets are jetted, the satellites can be caused to land on the electrical component mounting board 1000 without being separated from the main droplets.

[2]

The same jetting frequency as a jetting frequency, which is applied to the jet of the liquid during the second relative movement, is applied to the jet of the liquid during the first relative movement. Accordingly, the volume of the conductive ink, which is jetted per unit time in the jet of the liquid during the first relative movement, is equal to that in the jet of the liquid during the second relative movement, so that a reduction in productivity can be suppressed.

[3]

A relative movement speed, which is ¾ times or less a relative movement speed applied to the second or subsequent relative, is set in the first relative movement. Accordingly, a conductive pattern in which relatively high printing position accuracy is ensured can be printed in the jet of the liquid during the first relative movement.

[4]

In a case where a plurality of types of liquid droplets having volumes different from each other can be jetted, a type of liquid droplets, in which satellites are less likely to be generated, is applied to the conductive pattern that is formed in the jet of the liquid during the first relative movement. Accordingly, the generation of satellites in the jet of the liquid during the first relative movement is suppressed.

[5]

In a case where a plurality of types of liquid droplets having volumes different from each other can be jetted, a type of liquid droplets having the smallest size is applied to the jet of the liquid during the first relative movement. Accordingly, the generation of satellites in the jet of the liquid during the first relative movement is suppressed.

[6]

A drive voltage waveform, which includes one pulse contributing to a jet, is applied to the jet of the liquid during the first relative movement. Accordingly, constant jetting performance of the ink jet head 12 is ensured, so that a conductive pattern in which constant printing position accuracy is ensured can be printed.

[7]

A distance between the electrical component mounting board 1000 and the ink jet head 12 is reduced in the first relative movement as compared to the second or subsequent relative movement. Accordingly, it is expected that the printing position accuracy of a conductive pattern is improved in the jet of the liquid during the first relative movement as compared to the jet of the liquid during the second or subsequent relative movement, and collision between the electrical component mounting board 1000 and the ink jet head 12 is avoided due to the stable transport of the electrical component mounting board 1000.

In the embodiment of the present invention described above, the configuration requirements can be changed, added, or deleted as appropriate without departing from the spirit of the present invention. The present invention is not limited to the embodiment described above, and many modifications can be made by a person having ordinary knowledge in the art within the technical idea of the present invention. In addition, the embodiment, modification examples, and application examples may be combined as appropriate.

### EXPLANATION OF REFERENCES

10: liquid jet apparatus

12: ink jet head

20: transport device

22: table

24: board moving mechanism

26: head lifting device

30: base

100: system control unit

102: pattern data acquisition unit

104: pattern data processing unit

106: jet control unit

108: transport control unit

110: head lifting control unit

112: jet cycle setting unit

114: liquid droplet type setting unit

115: drive voltage generation unit

116: transport speed setting unit

120: memory

122: sensor

200: control device

202: processor

204: computer-readable medium

206: communication interface

208: input/output interface

210: bus

214: input device

216: display device

220: data acquisition control program

222: data processing control program

224: jet control program

226: transport control program

228: head lifting program

1000: electrical component mounting board

1002: printed wiring board

1004: component mounting surface

1006: IC

1008: resistor

1009: electrode

1010: capacitor

1011: electrical component

1020: conductive pattern

1200: conductive pattern

1202: dot

1204: boundary dot

1206: satellite dot

1400: conductive pattern

1402: dot

1404: dot

1406: boundary dot

1500: drive voltage waveform

1502: waveform element

1504: waveform element

1510: drive voltage waveform

1512: waveform element

1514: waveform element

1516: waveform element

1520: drive voltage waveform

1522: waveform element

1524: waveform element

1526: waveform element

1530: drive voltage waveform

1532: first pulse

1534: second pulse

1540: drive voltage waveform

1542: first pulse

1544: second pulse

L: allowable range

S10 to S28: each step of method of manufacturing pattern-formed board

What is claimed is:

1. A method of manufacturing a pattern-formed board by performing a plurality of times of relative movement of between board and a liquid jet head and jetting liquid to the board from the liquid jet head during each relative movement to form a pattern on the board, the method comprising:
performing a first relative movement and jetting the liquid from the liquid jet head to form a first pattern element on the board;
performing a second relative movement and jetting the liquid from the liquid jet head to form a second pattern element in a region of the first pattern element so as to be superimposed on the first pattern element and to form the pattern including the first pattern element and the second pattern element; and
applying a relative movement speed, which is lower than a relative movement speed of the second relative movement, to the first relative movement.

2. A liquid jet apparatus comprising:
a liquid jet head that jets liquid to a board;
a moving device that moves the board and the liquid jet head relative to each other;
at least one processor; and
at least one memory that stores a command to be executed by the at least one processor,
wherein the at least one processor is configured to:
control the moving device to perform a first relative movement of a plurality of times of relative movement between the board and the liquid jet head;
jet the liquid to the board from the liquid jet head during the first relative movement to form a first pattern element on the board;
control the moving device to perform a second relative movement;
jet the liquid from the liquid jet head during the second relative movement to form a second pattern element in a region of the first pattern element so as to be superimposed on the first pattern element and to form a pattern including the first pattern element and the second pattern element; and
apply a relative movement speed, which is lower than a relative movement speed of the second relative movement, to the first relative movement.

3. The liquid jet apparatus according to claim 2,
wherein the at least one processor is configured to apply a driving frequency of the liquid jet head, which is applied to the jet of the liquid during the second relative movement, to the jet of the liquid during the first relative movement.

4. The liquid jet apparatus according to claim 2,
wherein the at least one processor is configured to control the moving device such that a relative movement speed lower than an average of a relative movement speed of the second or subsequent relative movement is applied to the first relative movement.

5. The liquid jet apparatus according to claim 2,
wherein the at least one processor is configured to control the moving device such that a relative movement speed, which is ¾ times or less a relative movement speed set for the second relative movement, is applied to the first relative movement.

6. The liquid jet apparatus according to claim 2,
wherein the at least one processor is configured to select a liquid droplet size in which satellites are less likely to be generated in a case where a liquid droplet size to be applied the jet of the liquid during the first relative movement is to be selected from a plurality of types of liquid droplet sizes.

7. The liquid jet apparatus according to claim 2,
wherein the at least one processor is configured to select a smallest liquid droplet size in a case where a liquid droplet size to be applied the jet of the liquid during the first relative movement is to be selected from a plurality of types of liquid droplet sizes.

8. The liquid jet apparatus according to claim 2,
wherein the liquid jet head comprises a piezoelectric element that applies pressure to the liquid in a case where the liquid is jetted, and
the at least one processor is configured to supply a drive voltage, which includes one pulse-shaped voltage contributing to the jet, to the piezoelectric element in the jet of the liquid during the first relative movement.

9. The liquid jet apparatus according to claim 2, further comprising:
a change device that changes a distance between the board and the liquid jet head,
wherein the at least one processor is configured to control the change device to apply a distance, which is shorter than a distance between the board and the liquid jet head applied to the second relative movement, as a distance between the board and the liquid jet head that is applied to the first relative movement.

10. The liquid jet apparatus according to claim 2,
wherein the at least one processor is configured to jet the liquid to a boundary position of a pattern to be formed on the board during the first relative movement and to jet the liquid to a non-boundary position of a pattern to be formed on the board during the second relative movement.

11. The liquid jet apparatus according to claim 2,
wherein the liquid jet head jets conductive liquid having conductivity.

12. The liquid jet apparatus according to claim 11,
wherein an electrical component mounting board on which an electrical component is mounted is applied as the board, and
the at least one processor is configured to jet the conductive liquid to an electrical component-disposition region, in which the electrical component is disposed, from the liquid jet head.
